(19) United States
(12) Patent Application Publication
(10) Pub. No.: US 2023/0299516 A1
(43) Pub. Date: Sep. 21, 2023

(54) DOUBLE-SIDED ULTRA SLIM MODULE CONNECTOR

(71) Applicant: Intel Corporation, Santa Clara, CA (US)

(72) Inventors: Amarjeet KUMAR, Bangalore (IN); Navneet Kumar SINGH, I, Bangalore (IN); Samarth ALVA, Bangalore (IN); Richard S. PERRY, pORTLAND, OR (US); Christopher WEST, Portland, OR (US)

(73) Assignee: Intel Corporation, Santa Clara, CA (US)

(21) Appl. No.: 18/202,194

(22) Filed: May 25, 2023

(51) Int. Cl. H01R 12/52; H05K 7/20

(52) U.S. Cl. CPC H01R 12/52; H05K 7/20509

(57) ABSTRACT

A back-to-back ultra-slim module (USM) includes an inline USM (USMi) connector and a top mount USM (USMt) connector. The back-to-back USM assembly can be made as a double-sided module to allow a stacked module configuration to save system area. The stacked module has a USMi module inline with the system board on one side of the system board, and a USMt module vertically offset from the other side of the system board. The stacked module can have a thermal layer between the USMi module and the USMt module.

### TECHNICAL FIELD

Descriptions are generally related to interconnects, and more particular descriptions are related to architectures for an ultra slim connector.

### BACKGROUND OF THE INVENTION

Consumer demand is increasing for smartphones, tablets, and very slim computing devices, including thinner profiles for laptop devices. Such devices have been designed with a motherboard or primary system printed circuit board (PCB) that includes the host processor and system memory, and add-in boards to provide certain peripherals. The add-in boards can be referred to as modules that are incorporated into the system by connecting to the system board. The use of modules allows a more modular design to use different components for different models of devices (e.g., the amount of storage or the type of wireless connectivity).

Low profile systems (e.g., systems designed for low vertical or z-height) can be constrained by M.2 modules. Some systems are designed for higher performance without as much emphasis on z-height, which tend to be more sensitive to thermal system performance, which can be impacted by modules. With an increase in the number of modules incorporated in a system, the system board may have more connectors to couple the modules to the system.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a computer system with a double ultra slim module (USM) connector configuration to mount modules to a system board.

FIG. 2 is a block diagram of an example of a USM connector configuration with an inline USM connector (USMi) and a top-mounted USM connector (USMt).

FIG. 3A is a block diagram of an exploded view of a USMi connector and USMt connector mounted to a system board.

FIG. 3B is a block diagram of the system of FIG. 3A.

FIG. 4A is a cutaway diagram of an example of a USMi connector.

FIG. 4B is a cutaway diagram of an example of a USMt connector.

FIG. 4C is an example of a beam contact for an inline USM connector.

FIG. 4D is an example of a beam contact for a top mount USM connector.

FIG. 5 is a diagram of an example of a pin assembly or a frame of leads for a USM connector.

FIGS. 6A-6G are diagrams of an example of a double USM connector assembly.

FIG. 7 is an example of a USM module connected to a plate.

FIG. 8 is an example of a double USM connector assembly with a cutaway view.

FIGS. 9A-9B are diagrams of an example of a USMi connector for use in a double USM connector assembly.

FIG. 10A-10B are block diagrams of an example of a computer system with a system board to accommodate a double USM connector assembly.

FIG. 10C is a block diagram of an example of a computer system with a double USM connector assembly mounted to a ruler board.

FIG. 11 is a block diagram of an example of a computing system in which a double USM connector assembly can be implemented.

FIG. 12 is a block diagram of an example of a mobile device in which a double USM connector assembly can be implemented.

Descriptions of certain details and implementations follow, including non-limiting descriptions of the figures, which may depict some or all examples, and well as other potential implementations.

### DETAILED DESCRIPTION OF THE INVENTION

As described herein, a double sided ultra-slim module (USM) assembly includes an inline USM (USMi) connector and a top mount USM (USMt) connector to enable connecting different modules back-to-back to a system board. The back-to-back USM assembly allows a stacked module configuration to save system area. The stacked module has a USMi module inline with the system board on one side of the system board, and a USMt module mounted to the back of the USMi module, and mounted vertically offset from the other side of the system board. The stacked module can have a thermal layer between the USMi module and the USMt module.

In one example, a USMi connector has a very low profile to interconnect modules to a system board, where the USMi connector includes electrical leads to bridge from one board to another board, to interconnect pads on one surface of the boards. The boards can interconnect with the inline USM connector while aligned in substantially the same plane.

In one example, a USMt connector has a very low profile to interconnect modules to a system board, where the USMt connector includes electrical leads to bridge from one board to another board, to interconnect pads on one surface of the boards. The boards can interconnect when one board is not co-planar with the other board, but has one surface vertically offset from the surface of the board to connect to.

Both the inline USM connector and the top mount USM connector include a lead frame including the electrical leads and an alignment frame to hold the lead frame. Both connectors can include a conductive case to secure over the alignment frame, which reduces electromagnetic interference (EMF) radiation from the connector leads. The connectors include screw holes to allow screws to secure the connector in place against the boards and ensure electrical connection between the pads on the two boards through the electrical leads of the connector. The alignment frame includes posts to mate with alignment holes in the boards to key the connectors to the boards and ensure proper alignment of the connector leads with the pads on the boards.

The USMi and USMt connectors connect to contacts on only one side of a printed circuit board (PCB). The use of contacts on only one side of the PCB allows USM connectors to have lower z-height than connectors that connect to contacts on both sides of the PCB, such as M.2 connectors. Additionally, there is no known configuration of an M.2 connector that enables stacking two modules vertically in the connector. The mechanical limitations and thermal design constraints suggest against any such M.2 stacked configuration. As described herein, a connector assembly can have stacked modules connected to opposite sides of the system board. Such a double-sided or dual-sided module includes two USM connectors, one on each side of the system board.

The stacking of the modules makes use of available z-height in a system, while reducing the x-y footprint of incorporating two modules into the system. In one example, the modules have a thermal layer between them to provide improved thermal performance of the stacked modules. With such a thermal layer, the system can address the thermal conditions introduced by the stacked modules. The thermal layer between the modules can address the thermal performance of the modules regardless of the system board PCB thickness.

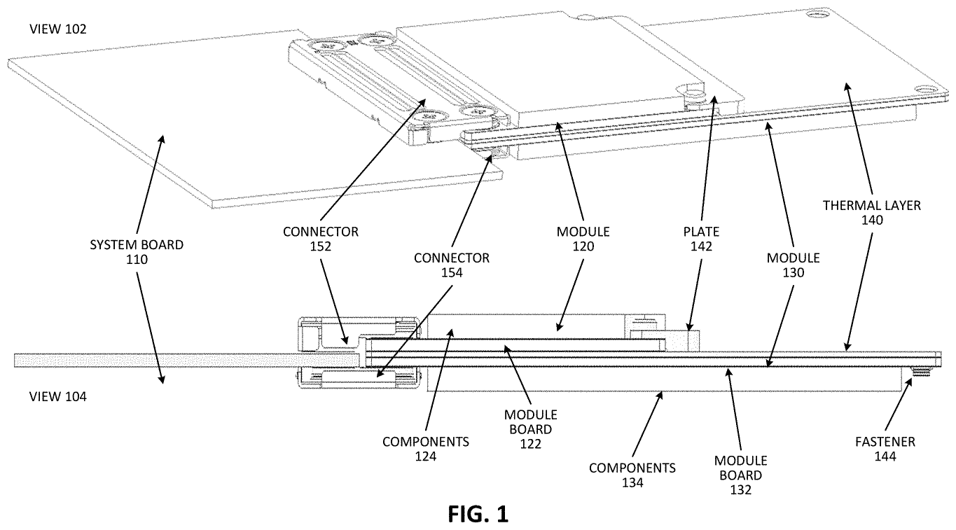

FIG. 1 is a block diagram of an example of a double ultra slim module (USM) connector configuration to mount modules to a system board. View 102 represents a perspective view and view 104 represents a side view.

The system includes system board 110, which represents a primary system PCB, such as a motherboard. In one example, system board 110 is a computer motherboard. Module 120 represents a first module to connect to system board 110. Module 130 represents a second module to connect to system board 110. Module 120 includes module board 122, which is a PCB board, with one or more components 124 mounted to module board 122. Similarly, module 130 includes module board 132 with one or more components 134 mounted to module board 132.

In one example, module 120 and module 130 are the same type of module. In one example, module 120 and module 130 are different kinds of modules. As illustrated, the modules can be different sizes. Alternatively, the modules can be of the same size. The modules can be any combination of USM module size. The modules can be add-in components for memory/storage, such as dual inline memory modules (DIMMs) or solid state drives (SSDs). The modules can be add-in components for wireless communication, such as WiFi, Bluetooth (BT), WWAN (wireless wide area network) such as cellular, or other wireless communication.

Thermal layer 140 represents a board or a plate between module board 122 and module board 132. In one example, thermal layer 140 is a metal plate. In one example, the plate is made of a metallic alloy, such as an aluminum-copper alloy. In one example, the plate is a steel-copper alloy.

In one example, module 120 is mounted to thermal layer 140 with a removable fastener. Examples of fasteners can include a nut and bolt, whether a hand-tightened nut or a tool-tightened nut, a plate or other sliding securing feature, screws, or other fastener. As illustrated, module 120 is secured to thermal layer 140 with plate 142, which can slide over mounting posts on thermal layer 140.

Module 130 can be mounted to thermal layer 140 similarly to module 120. As illustrated, module 130 is mounted to thermal layer 140 with fastener 144, such as a screw. In general, the back-to-back module configuration can refer to mounting one module to one side of the thermal layer and the other module to the other side of the thermal layer.

Connector 152 secures module 120 to system board 110 and provides electrical connection from contacts (not specifically illustrated) on module board 122 with contacts (not specifically illustrated) on one side (one surface) of system board 110. Connector 154 secures module 130 to system board 110 and provides electrical connection from contacts (not specifically illustrated) on module board 132 with contacts (not specifically illustrated) on the other side (other surface) of system board 110.

In one example, connector 152 represents a USMt connector, with the surface of module 120 vertically offset relative to the surface of system board 110 to which it connects. In one example, connector 154 represents a USMi connector, with the surface of module 130 vertically aligned with the surface of system board 110 to which it connects. As mentioned above, either module can be of any module size supported by USM.

Consider an implementation where module 120 connects to the top surface of system board 110 and module 130 connects to the bottom surface of system board 110. In such an implementation, module 120 connects to the top surface of system board 110 with a USMt connector, and module 130 connects to the bottom surface of system board 110 with a USMi connector. In another implementation, the surface of module 120 can be aligned with the top surface of system board 110 and connected to the top surface with a USMi connector (e.g., an implementation where connector 152 is a USMi connector). In that other implementation, the surface of module 130 could be vertically offset relative to the bottom surface of system board 110, and module 130 can be connected to the bottom surface with a USMt connector (e.g., an implementation where connector 154 is a USMt connector).

Thermal layer 140 can act as a thermal spreader to remove heat from module 120 and module 130 in active operation. The thermal spreader can effectively transport and dissipate heat from the modules. The stacked approach achieves the z-height benefits of USM while reducing the x-y footprint in the system. The x-y savings can enable a decreased system size, an increased battery size for the same system size, and enable different system configurations. In one example, the combination of a USMt connector and a USMi connector can be implemented with configurations such as a USMt with SSD or WWAN with a USMi with SSD. The addition of multiple SSDs can support a redundant array of independent drives (RAID) configuration in a small form factor computing device.

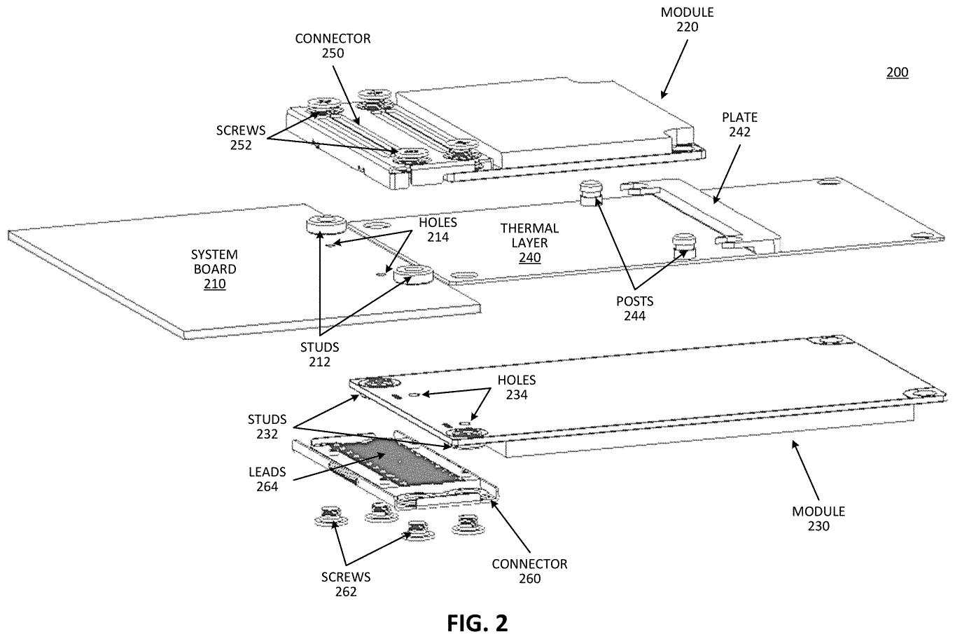

FIG. 2 is a block diagram of an example of a USM connector configuration with an inline USM connector (USMi) and a top-mounted USM connector (USMt). System 200 illustrates an example of the system of view 102 and view 104 of FIG. 1. System 200 illustrates components separated from each other, where the system in FIG. 1 is illustrated as assembled.

System 200 includes system board 210 to which module 220 and module 230 will be connected. Connector 250 connects module 220 to system board 210. Connector 260 connects module 230 to system board 210. Thermal layer 240 is between module 220 and module 230. Thermal layer 240 includes posts 244 to which plate 242 can slide onto and secure module 220 to thermal layer 240. In one example, thermal layer 240 can have corrugation or fins on a portion that will be exposed to air. Thus the portion on the surface of thermal layer 240 to which module 220 is attached could include fins or other feature to help dissipate heat.

In one example, plate 242 represents a spring loaded mechanism to mount module 220. It will be understood that a spring-loaded mechanism saves assembly and disassembly time relative to the use of screws or bolts. Plate 242 can be referred to as a sliding plate.

System board 210 includes studs 212 over mounting holes in the system board to provide the vertical offset for connector 250. In one example, studs 212 can be referred to as standoffs. The studs/standoffs can enable system 200 to have USM connectors back-to-back in the same holes of system board 210.

Studs 212 can be mounted securely to system board 210, such as through adhesive or through solder. Studs 212 can be threaded, allowing screws 252 to secure connector 250 to studs 212, which can then secure it to system board 210. In one example, there are screws that secure to threaded holes in the board of module 220.

In one example, system board 210 includes holes 214, which provide alignment to mounting posts of connector 250 (not specifically shown) and to mounting posts of connector 260 (not specifically shown). In one example, the board of module 220 also has alignment holes to align connector 250.

In one example, module 230 includes studs 232 to provide threading to mount connector 260 to module 230. In one example, the board of module 230 includes holes 234 for alignment of connector 260 to the module. Screws 262 can secure connector 260 through system board 210 to studs 212. The perspective of system 200 illustrates the inside of connector 260, which illustrates leads 264. Leads 264 represent a lead frame to connect contacts of module 230 with contacts of system board 210.

With the addition of studs 232, system 200 can utilize USMt and USMi connectors without other changes to the connectors from single-connector configurations. In one example, plate 242 and posts 244 enable the securing of modules of different lengths to thermal layer 240, enabling the use of different module sizes in the stacked configuration.

In one example, thermal layer 240 acts as a common heatsink for module 220 and module 230 as well as providing a mechanical platform on which to mount the different modules. The mechanical platform can be particularly useful for modules of different sizes. In one example, the mechanical platform enables the use of modules that are unmodified relative to configurations that do not use module stacking.

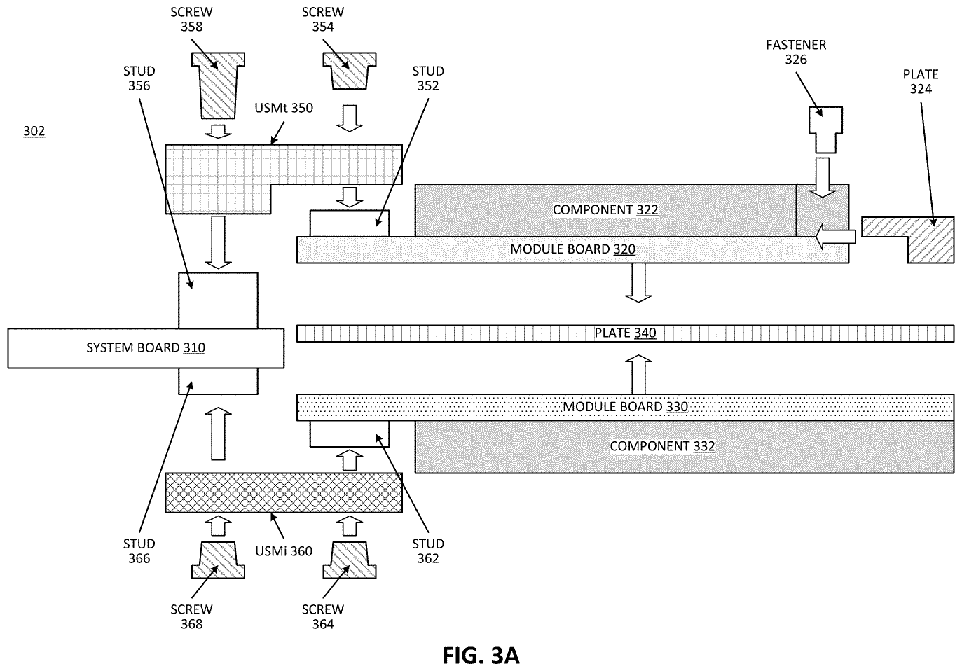

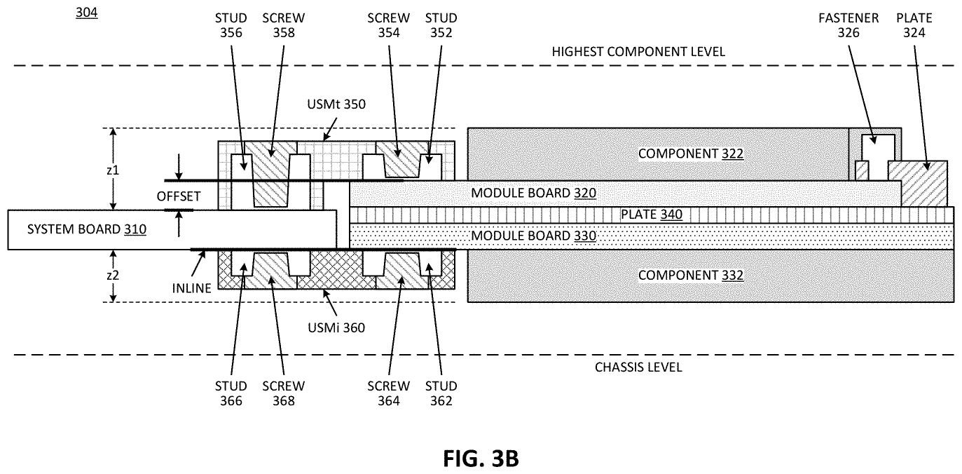

FIG. 3A is a block diagram of an exploded view of a USMi connector and USMt connector mounted to a system board. System 302 is a system in accordance with an example of system 200. It will be understood that system 302 provides only a partial view of the components, and the elements are not necessarily to scale.

System board 310 represents a PCB of a host system. System board 310 includes a processor and interconnect components. Module board 320 represents a board of a first module. Component 322 is mounted on module board 320. Module board 330 is a second module of system 302. Component 332 is mounted on module board 330.

In one example, USMt 350 connects module board 320 to system board 310. USMt 350 represents a top-mount ultra-slim module connector having an offset lead frame to bridge from pads on one surface of system board 310 to a surface of module board 320 when the respective surfaces of the module board and the system board are vertically offset.

In one example, USMi 360 connects module board 330 to system board 310. USMi 360 represents an inline ultra-slim module connector having an inline lead frame to bridge from pads on the other surface of system board 310 to a surface of module board 330 when the respective surfaces of the module board and the system board are vertically inline with each other.

System 302 includes plate 340. Module board 320 and module board 330 are mounted to plate 340. In one example, module board 320 can be mounted to plate 340 with fastener 326, secured by plate 324, which can be slid over fastener 326.

In one example, module board 320 has stud 352, which can be a threaded mounting stud to attach USMt 350 to module board 320. Screw 354 secures USMt 350 to stud 352. In one example, module board 330 has stud 362, which can be a threaded mounting stud to attach USMi 360 to module board 330. Screw 364 secures USMi 360 to stud 362.

In one example, system board 310 has stud 356, which can be a threaded mounting stud to attach USMt 350 to system board 310. Screw 358 secures USMt 350 to stud 356. In one example, system board 310 has stud 366, which can be a threaded mounting stud to attach USMi 360 to system board 310. Screw 368 secures USMi 360 to stud 362.

With use of a USMt connector and a USMi connector, the different studs attaching system board 310 to the different connectors can be of different lengths. The different lengths can accommodate the differences in relative vertical offsets between the system board and the module boards.

FIG. 3B is a block diagram of the system of FIG. 3A. System 304 represents system 302 assembled. As illustrated, module board 320 is mounted to plate 340, secured by fastener 326 and plate 324. Module board 330 is mounted to plate 340, where the securing mechanism is not seen in the view illustrated.

As illustrated, when assembled, module board 320 has a surface offset with respect to system board 310. USMt 350 secures module board 320 to system board 310, with screw 354 in stud 352 and screw 358 in stud 356. The total vertical height of the USMt module is z1, which is measured from the surface of system board 310 to which the module connects, up to the height of component 322. In one example, the USMt module is mounted to a top surface of system board 310, between the system board and the highest component level, as indicated by the dashed line showing the level of the highest component. The highest component is typically the processor, with a fan mounted on the processor system on a chip (SOC).

As illustrated, when assembled, module board 330 has a surface inline with system board 310. USMi 360 secures module board 330 to system board 310, with screw 364 in stud 362 and screw 368 in stud 366. The total vertical height of the USMi module is z2, which is measured from the surface of system board 310 to which the module connects, up to the height of component 332. In one example, the USMi module is mounted to a bottom surface of system board 310, between the system board and the chassis, as indicated by the dashed line showing the chassis level.

The drawings or system 304 and system 302 suggest that screw 364 is screwed into stud 362 from below module board 330, entering from the edge of USMi 360 and continuing toward module board 330. In an alternate implementation, which is shown below, screw 364 can be screwed in through module board 330 into stud 362, toward the outer edge of USMi 360.

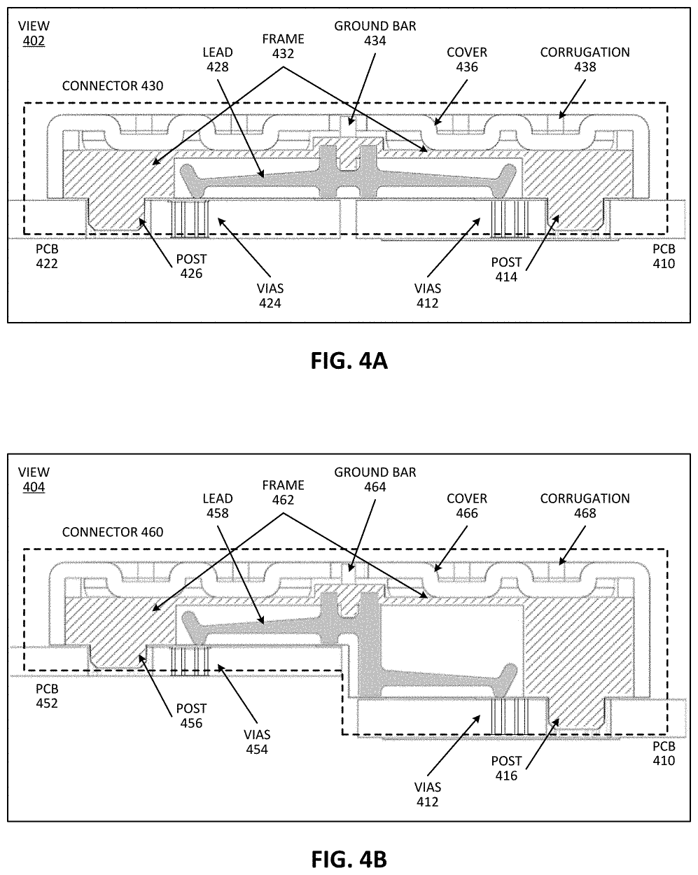

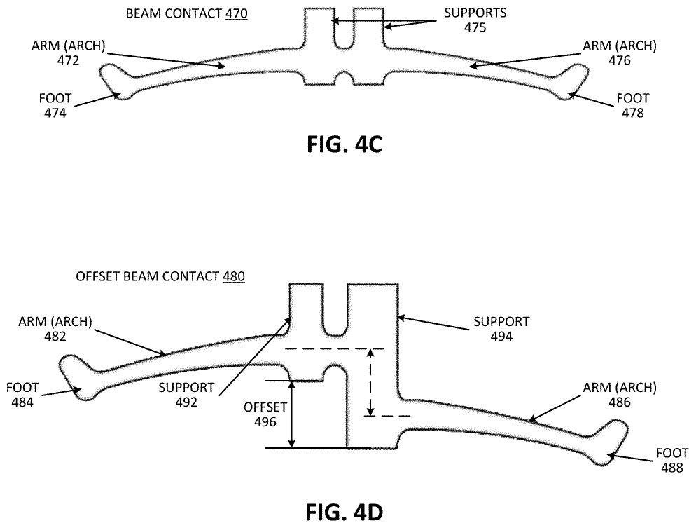

FIG. 4A is a cutaway diagram of an example of a USMi connector. View 402 illustrates a cutaway view of connector 430 connecting PCB 422, which represents a module board, to PCB 410, such as a motherboard. It will be understood that view 402 illustrates an example of a USMi connector, which can be one of the connectors used in a back-to-back configuration with a USMt connector.

Connector 430 is represented by the features surrounded by the dashed line. Connector 430 includes leads 428. While not specifically labeled, it will be observed that lead 428 includes one foot to contact pads on PCB 410 and another foot to contact pads on PCB 422. In one example, lead 428 has a curved form, which can provide a spring force when connector 430 is secured by screws (not shown). More specifically, leads 428 can be implemented as an arch-shaped spring, which has some flex due to force applied from cover 436.

In one example, leads 428 include arms extending from a middle point to each side to the foot that physically and electrically contacts the signal pad. In one example, connector 430 includes ground bar 434, which runs down the middle between the vertical arms of leads 428. In one example, ground bar 434 includes tabs that extend down between the vertical arms for leads to be selectively contacted, and does not include tabs for signal lines not to be connected to ground. The spring action of leads 428 can operate to ensure secure physical and electrical contact between ground leads and ground bar 434.

Connector 430 includes frame 432, which secures leads 428. In one example, frame 432 includes post 414 and post 426, which represent posts or tabs or extensions of the frame to extend into or through the PCBs. Post 414 represents a pair of keying features to align with keying holes in PCB 410. Post 426 represents a pair of keying features to align with keying holes in PCB 422.

Connector 430 includes cover 436 to enclose the leads and frame 432. Connector 430 includes screw holes (not shown) to secure connector 430 to PCB 410 and to PCB 422. In one example, cover 436 includes corrugation features 438 as stiffening features. Corrugation 438 enables cover 436 to withstand the stress of the forces of the spring action of leads 428.

View 402 illustrates vias 412 in PCB 410 and vias 424 in PCB 422. Vias 412 and vias 424 represent electrical vias to connect signal line pads on the PCBs to connect to the ground plane on the respective PCBs. Thus, the ground leads can be connected to the ground plane through pads on the surfaces of the PCBs, through vias to the ground plane, and also to cover 436, which can also connect to the ground planes through screws.

FIG. 4B is a cutaway diagram of an example of a USMt connector. View 404 illustrates a cutaway view of connector 460 connecting PCB 452, which represents a module board, to PCB 410. It will be understood that view 404 illustrates an example of a USMt connector, which can be one of the connectors used in a back-to-back configuration with the USMi connector of view 402. It will be understood that the orientation of the connectors and boards does not illustrate that one connector will be on one side of the system board and the other connector will be on the other side of the system board.

Connector 460 is represented by the features surrounded by the dashed line. Connector 460 includes leads 458. While not specifically labeled, it will be observed that lead 458 includes one foot to contact pads on PCB 410 and another foot to contact pads on PCB 452, where the legs and feet of leads 458 are vertically offset. In one example, lead 458 has a curved form, which can provide a spring force when connector 460 is secured by screws (not shown). More specifically, leads 458 can be implemented as an arch-shaped spring, which has some flex due to force applied from cover 466.

In one example, leads 458 include arms extending from a middle point to each side to the foot that physically and electrically contacts the signal pad. In one example, connector 460 includes ground bar 464, which runs down the middle between the vertical arms of leads 458 and selectively contacts signal lines that are to be grounded. The spring action of leads 458 can operate to ensure secure physical and electrical contact between ground leads and ground bar 464.

Connector 460 includes frame 462, which secures leads 458. In one example, frame 462 includes post 416 and post 456, which represent posts or tabs or extensions of the frame to extend into or through the PCBs. Post 416 represents a pair of keying features to align with keying holes in PCB 410. Post 456 represents a pair of keying features to align with keying holes in PCB 452. In one example, the keying features do not extend all the way through PCB 410, to enable the keying features of the companion USM connector to use the same keying holes.

Connector 460 includes cover 466 to enclose the leads and frame 462. Connector 460 includes screw holes (not shown) to secure connector 460 to PCB 410 and to PCB 452. In one example, cover 466 includes corrugation features 468 as stiffening features. Corrugation 468 enables cover 466 to withstand the stress of the forces of the spring action of leads 458.

View 404 illustrates vias 412 in PCB 410 and vias 454 in PCB 452. Vias 412 and vias 454 represent electrical vias to connect signal line pads on the PCBs to connect to the ground plane on the respective PCBs. Thus, the ground leads can be connected to the ground plane through pads on the surfaces of the PCBs, through vias to the ground plane, and also to cover 466, which can also connect to the ground planes through screws.

FIG. 4C is an example of a beam contact for an inline USM connector. Beam contact 470 is a closer view of a contact in accordance with an example of lead 428 of the USMi connector in view 402.

Beam contact 470 illustrates supports 475 in the center of the contact, arm 472 having an arch shape, extending in one direction away from supports 475, and arm 476 having an arch shape, extending in the other direction away from supports 475. Arm 472 includes foot 474, which is the portion of the contact that will rest on the pad on the surface of the first board to connect. Arm 476 includes foot 478, which is the portion of the contact that will rest on the pad on the surface of the second board to connect. It will be understood that “first” and “second” boards are relative, and the designations can be reversed.

Arm 472 and arm 476 include arch shapes, having a curvature from supports 475 to foot 474 and from supports 475 to foot 478, respectively. The curvature allows beam contact 470 to flex. The flexion provides pressure on foot 474 and on foot 478 to maintain the feet in contact with their respective pads. The flex is created by a downward force exerted as the screws secure the connector to the boards.

FIG. 4D is an example of a beam contact for a top mount USM connector. Offset beam contact 480 is a closer view of a contact in accordance with an example of lead 458 of the USMt connector in view 404.

Offset beam contact 480 illustrates two supports in the center of the contact: support 492 is the shorter contact, and support 494 is the taller contact. Arm 482 has an arch shape, extending away from support 492, to foot 484. Foot 484 is the portion of the contact that will rest on the pad on the surface of the first board to connect. Arm 486 has an arch shape, extending away from support 494, to foot 488. Foot 488 is the portion of the contact that will rest on the pad on the surface of the second board to connect. It will be understood that “first” and “second” boards are relative, and the designations can be reversed.

The shorter support 492 connects to arm 482, which will connect with the board having the higher vertical position. The taller support 494 connects to arm 486, which will connect with the board having the lower vertical position. In one example, support 494 is thicker than support 492, which can enable the support to better pass the force from the connector down the additional vertical distance to arm 486.

Arm 482 and arm 486 include arch shapes, having a curvature from support 492 to foot 484 and from support 494 to foot 488, respectively. The curvature allows offset beam contact 480 to flex, and more specifically, to allow each arm to flex. The flexion provides pressure on foot 484 and on foot 488 to maintain the feet in contact with their respective pads. The flex is created by a downward force exerted as the screws secure the connector to the boards.

Offset 496 represents the vertical offset between the boards that will be connected by a connector with offset beam contact 480. It will be observed by the dashed lines and dashed arrow that offset 496 for the boards can match the offset between arm 482 and arm 486. Maintaining the arms with the same relative shape can maintain the same relative flex properties, with adjustments to the center support or supports to appropriately direct the force of the connector to the beams.

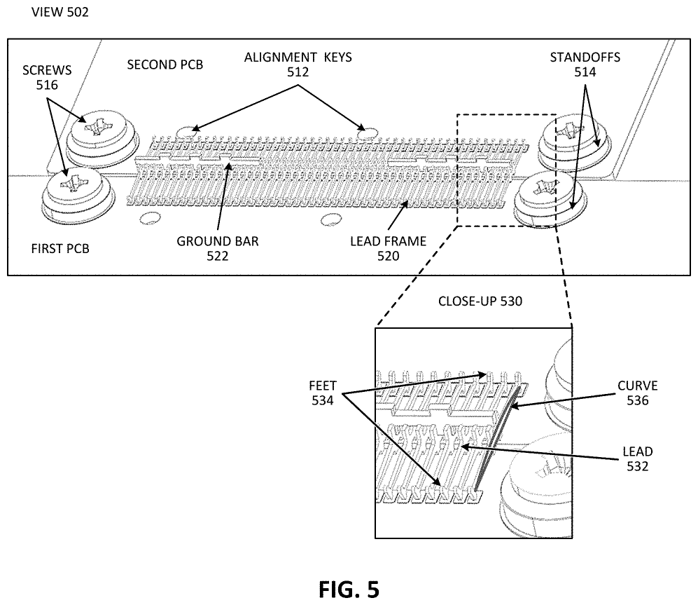

FIG. 5 is a diagram of an example of a pin assembly or a frame of leads for a USM connector. View 502 illustrates a pin assembly or a frame of leads to connect from pads on the first PCB with pads on the second PCB. Lead frame 520 represents the electrical leads or electrical connectors that make electrical connection between the pads on the first PCB with the pads on the second PCB when the connector is secured. The leads span the two rows of the connecting PCBs. View 502 specifically illustrates a lead frame for a USMi connector, and the lead frame for a USMt connector will be similar.

The electrical leads can also be referred to as pins or beam contacts. The leads or pins of lead frame 520 are bridges between the pads of the two devices or two boards. In one example, the pins are spring contacts that push against the upper plate or case of the connector. Close-up 530 illustrates an end of lead frame 520. Lead frame 520 is made up of multiple individual leads 532, which include feet 534. One foot makes contact with a pad on the first PCB and the other foot make contact with a corresponding pad on the second PCB. A straight line and curved line are illustrated and referenced as curve 536. The straight line illustrates the surface plane of the surfaces of the first PCB and the second PCB. The arc illustrates the curvature of one of the leads 532.

Alignment keys 512 (or alignment holes) illustrate keying or alignment structures to be engaged by an alignment frame of the connector. In one example, standoffs 514 electrically connect to a ground plane within the PCBs. In one example, screws 516 engage with standoffs 514. Alternatively, standoffs 514 could be threaded posts or studs that provide a threaded structure to secure screws 516.

In any configuration, screws 516 can electrically connect to a board ground or a system ground, grounding the connector. In one example, screws 516 also provide a thermal path for the connection, allowing the transfer of heat, which can also enable higher signaling rates. The heat can transfer to a ground plane of the module, which can also transfer to a plate between the two modules of a stacked module configuration.

In one example, the connector includes grounding bar 522 (which could alternatively be referred to as a grounding bar). Ground bar 522 can selectively connect to ground pins of lead frame 520. The connection of ground bar 522 to ground pins can ensure that each pin has a strong path to ground. If the connector cover is metal, ground bar 522 can physically contact the metal cover, providing a strong ground path through screws 516 and standoffs 514 to ground.

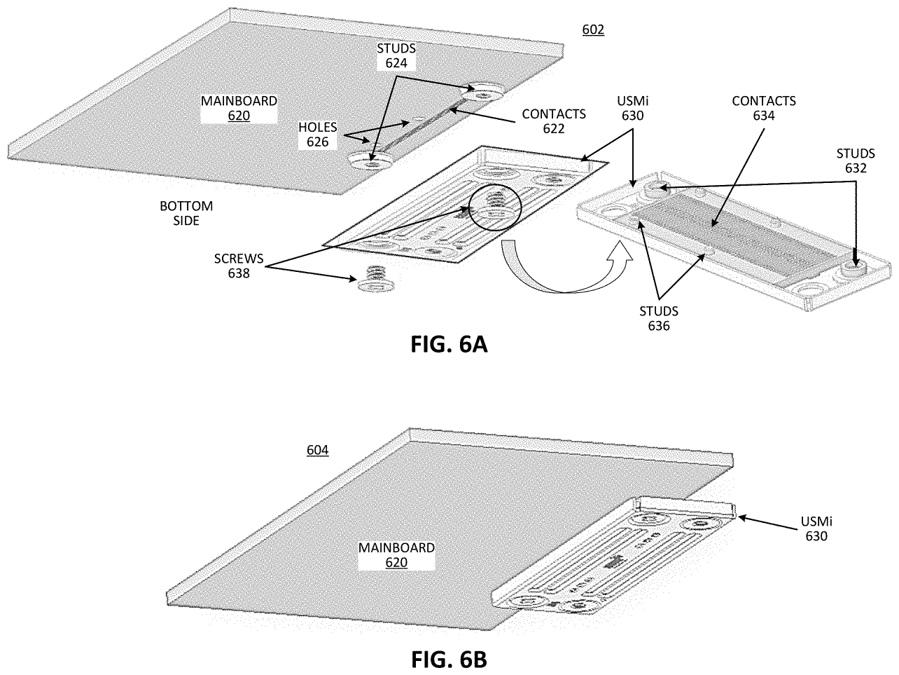

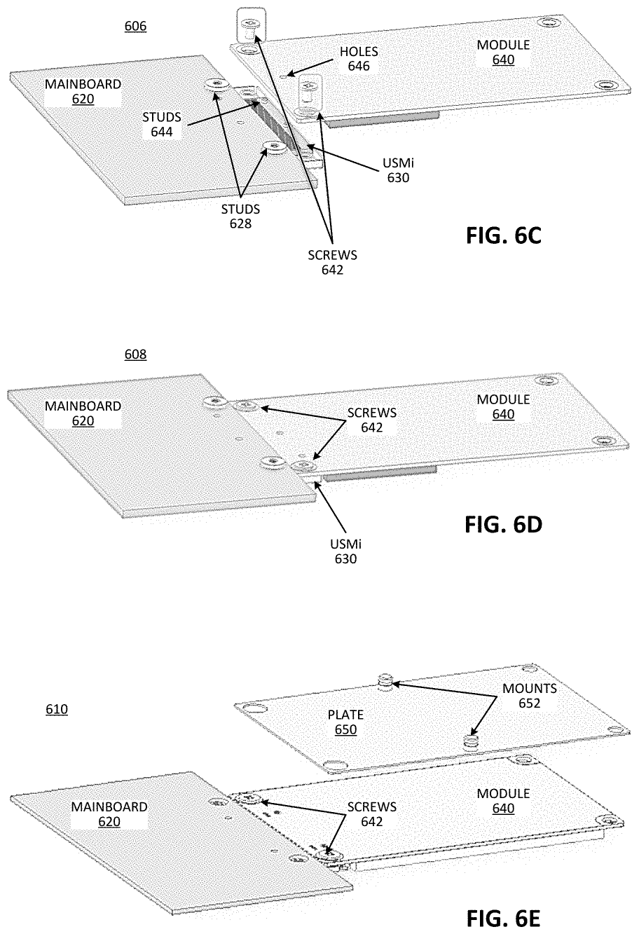

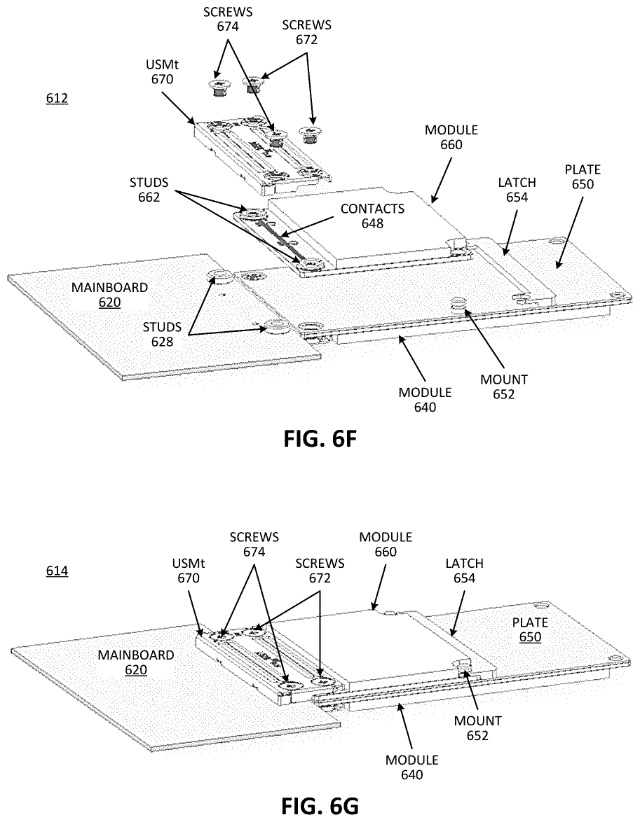

FIGS. 6A-6G are diagrams of an example of a double USM connector assembly.

FIG. 6A illustrates an example of a USMi connector to connect to the bottom side of a system board. Mainboard 620 represents the system board or the motherboard for a computing device. System 602 illustrates the bottom side of mainboard 620. Mainboard 620 includes contacts 622, which represent the metallic contacts on the bottom surface of mainboard 620 to connect to a module. In one example, mainboard 620 includes holes 626 as alignment features for USMi connector 630. Studs 636 of USMi connector 630 aligns with holes 626.

In one example, mainboard 620 includes studs 624, which can be threaded standoffs into which screws 638 can be screwed to secure USMi connector 630 to mainboard 620. USMi connector 630 includes contacts 634 to connect contacts 622 with contacts of a USMi module. In one example, USMi connector 630 includes studs 632, which can be threaded structures to receive screws to secure USMi connector 630 to the module board of the USMi module.

FIG. 6B illustrates the assembly of system 602 as assembled. System 604 includes USMi connector 630 connected to the bottom side of mainboard 620, where contacts 634 of USMi connector 630 will make electrical contact with contacts 622 of mainboard 620.

FIG. 6C illustrates an example of a module to connect to the bottom side of the system board with the USMi connector. System 606 illustrates the top side of mainboard 620. Module 640 represents a module to be mounted to the bottom side of mainboard 620 with USMi connector 630. In one example, USMi connector 630 includes studs 644 to match with holes 646 in the module board of module 640 for alignment.

In one example, module 640 is secured to USMi connector 630 with screws 642 that are mounted through the module board into the bottom side of USMi connector 630, as opposed to screws 638 that are inserted into the top side of USMi connector 630. The bottom side of USMi connector 630 refers to the side of the connector that is against the surface of the boards being connected. Thus, the top side of USMi connector 630 refers to the side of the connector opposite the surface to which it is being connected.

FIG. 6D illustrates the USMi connector securing the module to the bottom side of the system board. System 608 illustrates inline module 640 connected to mainboard 620 with USMi connector 630. Screws 642 secure module 640 to USMi connector 630.

FIG. 6E illustrates a thermal layer to be connected to the USMi module. System 610 includes plate 650, which represents a thermal layer in accordance with any example described. In one example, plate 650 is a metallic structure, and can be a metal alloy. In one example, plate 650 includes mounts 652 for a second module board that is shorter than plate 650. In one example, plate 650 is the same length as the module board of module 640.

FIG. 6F illustrates an example of a USMt connector to connect to the top side of the system board. System 612 illustrates the top side of mainboard 620 and plate 650. In one example, mainboard 620 includes studs 628 to mount USMt connector 670. System 612 does not specifically illustrate the contacts on mainboard 620.

Module 660 represents a second module for the system. Module 660 is to mount on plate 650, providing a stacked configuration with module 640. The stacked configuration refers to the stack of the two modules, which can include the thermal layer between the two modules. Reference to back-to-back configuration can indicate the same configuration, referring more specifically to the fact that the bottom of one module mounts to the bottom of the other module. Again, the configuration can include the bottom of one module mounting to one surface of the thermal layer, and the bottom of the other module mounting to the other surface of the thermal layer.

Module 660 includes contacts 648, which USMt connector 670 will connect with corresponding contacts on mainboard 620. In one example, module 660 includes studs 662 to connect USMt connector 670 to the module. System 612 illustrates screws 672 to secure USMt connector 670 to module 660 with studs 662. Screws 674 secure USMt connector 670 to mainboard 620 with studs 628. In one example, module 660 mounts to plate 650 with mounts 652 and latch 654. Latch 654 can refer to a sliding mechanism that spring-loads the module onto plate 650.

FIG. 6G illustrates the assembly of system 612 as assembled. System 614 includes the USMi connector 630 to connect module 640 to the bottom side of mainboard 620 and USMt connector 670 to connect module 660 to the top side of mainboard 620. System 614 illustrates screws 674 and screws 672 inserted into USMt connector 670 to connect module 660 to mainboard 620. Latch 654 and mount 652 can secure module 660 to plate 650.

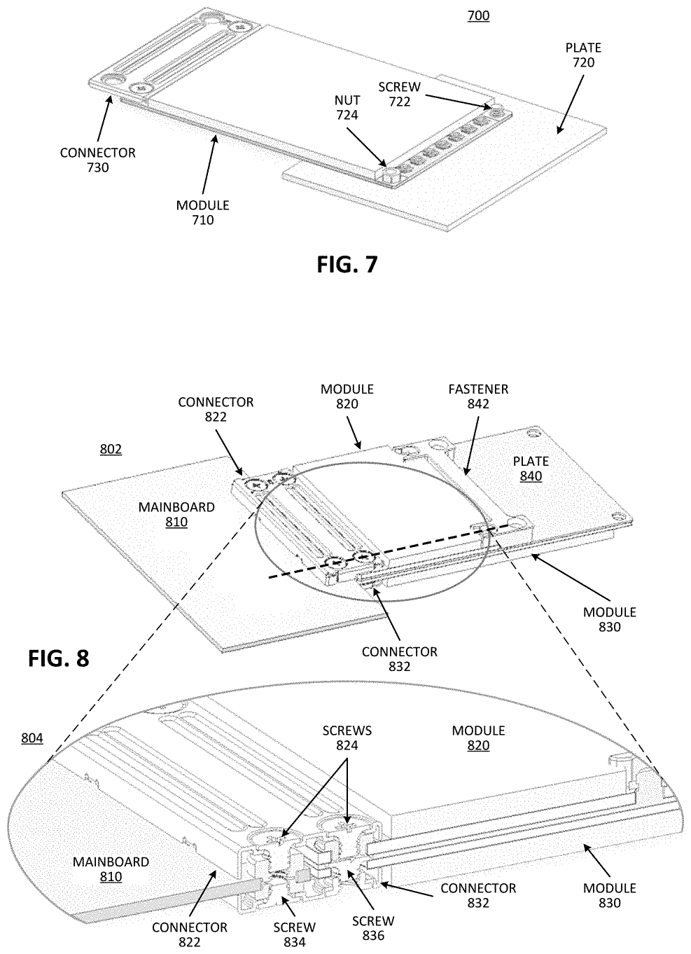

FIG. 7 is an example of a USM module connected to a plate. System 700 includes module 710 and plate 720. In one example, plate 720 will extend under more of module 710 or under all of module 710. The portion illustrated is for purposes of example.

Connector 730 secures module 710 to a system board. In one example, connector 730 is a USMi connector. Alternatively, connector 730 can be a USMt connector. System 700 is more specifically focused on the connection of module 710 to plate 720. In one example, system 700 includes screws 722, which can be screwed into plate 720 from the surface opposite the one on which module 710 is mounted. In one example, screw 722 is affixed to plate 720 as a mounting feature.

System 700 includes nut 724 to secure to the screw. In one example, screw 722 represents a threaded rivet bolt. In one example, nut 724 is a mechanically tightened nut, such as with a ratchet or wrench. In one example, nut 724 is a hand tightened nut, which typically will include features to increase grip on the nut to enable hand tightening.

FIG. 8 is an example of a double USM connector assembly with a cutaway view. System 802 represents a system in accordance with an example of system 200, or system 304, or system 614. View 804 specifically shows a cutaway view at the dashed line illustrated in system 802.

System 802 includes mainboard 810 and module 830. Module 830 has a surface that is inline with a surface of mainboard 810. Module 820 has a surface that is vertically offset relative to mainboard 810. Connector 822 connects module 820 to mainboard 810. Connector 832 connects module 830 to mainboard 810.

In one example, system 802 includes plate 840 between module 820 and module 830. Plate 840 can provide an optional thermal layer between the modules. In one example, module 820 is secures to plate 840 with fastener 842.

View 804 illustrates screws 824 that connect connector 822 to mainboard and to module 820. View 804 also illustrates screw 834 to secure connector 832 to mainboard 810 and screw 836 to secure module 830 to connector 832. In one example, screw 836 is inserted into a surface of module 830 that interfaces with plate 840 or the other module. Thus, it can be observed that screws 824 and screw 834 are inserted from the top side of connector 822 and connector 832, respectively, and screw 836 is inserted from a bottom side of connector 832.

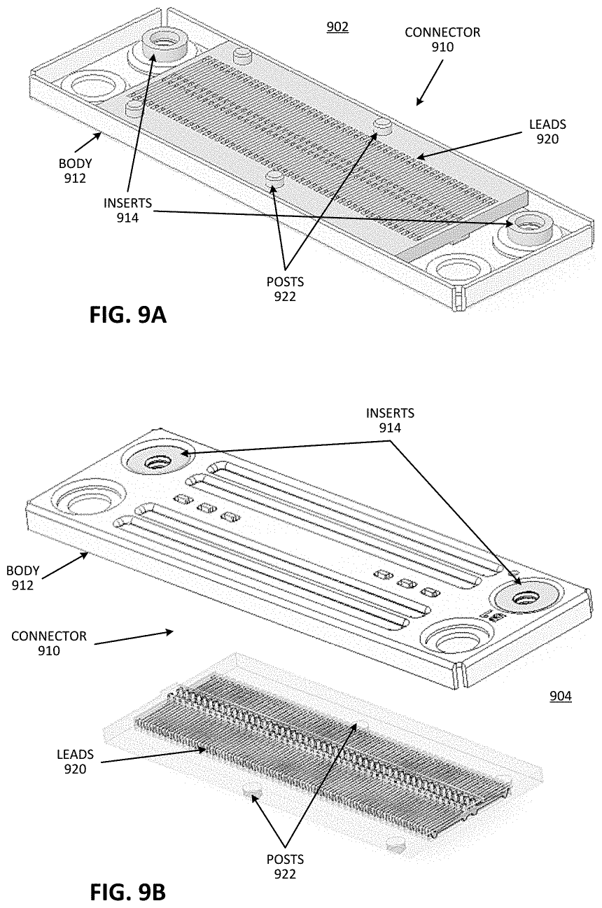

FIGS. 9A-9B are diagrams of an example of a USMi connector for use in a double USM connector assembly. Referring to FIG. 9A, view 902 illustrates connector 910 having body 912 and leads 920. The body can alternatively be referred to as the case or the cover. Leads 920 represents a lead frame to interconnect contacts on a module board with contacts on the system board.

Posts 922 represent alignment features that can align connector 910 with the PCBs of the system to ensure proper alignment of leads 920 with the PCB contacts. In one example, connector 910 includes inserts 914. Inserts 914 can be threaded features to enable screw mounting of the connector to the connector.

Referring to FIG. 9B, view 904 illustrates a top of body 912. View 904 illustrates inserts 914 in screw holes of body 912. The inserts can enable inserting screws from the other side of connector 910. View 902 illustrates a bottom side of leads 920, while view 904 illustrates the top of leads 920. In view 904, posts 922 can be seen through the lead frame. The top of body 912 illustrates the openings or holes in the cover to receive screws. Inserts 914 can be included in the openings corresponding to the module.

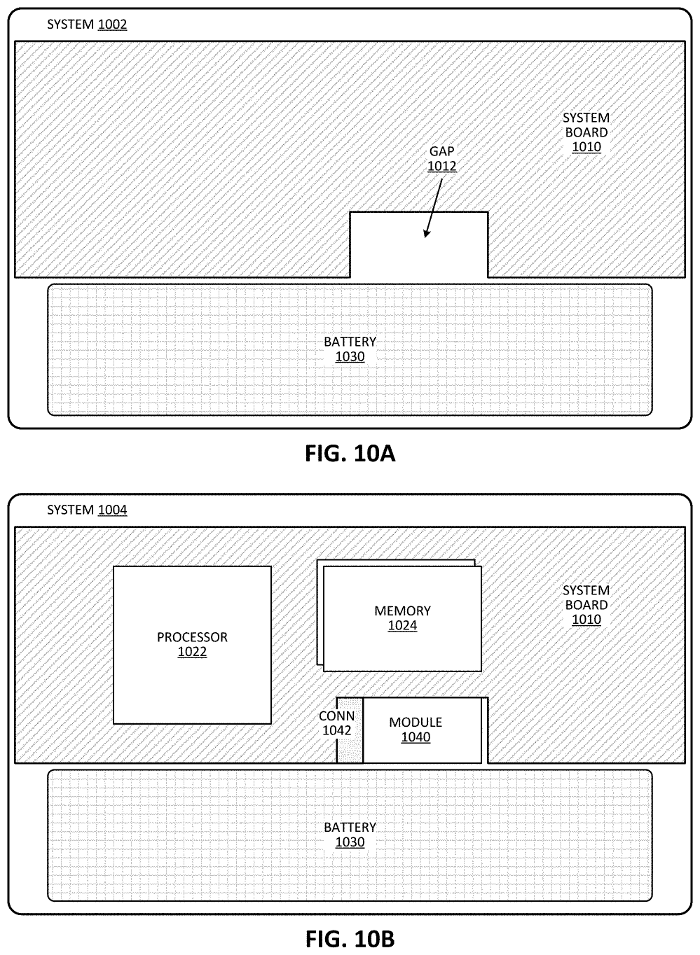

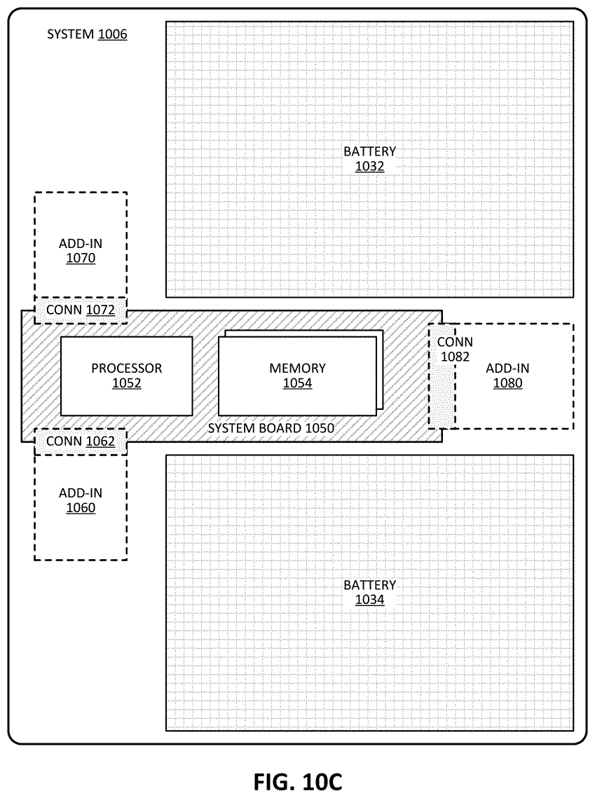

FIG. 10A is a block diagram of an example of a computer system with a system board to accommodate a double USM connector assembly. System 1002 represents a computing system or a computing device. For example, system 1002 can be a laptop computer, a tablet computer, or a two-in-one device. The display for the device is not explicitly shown in system 1002, but can be a screen that covers device, or can be a display that connects via hinge, built on top of the chassis of system 1002, or connect with some other connector.

In one example, system 1002 has a clamshell design, where the processing elements and keyboard are fixed to the display element. In one example, system 1002 is a detachable computer, where the processor and display are part of a common unit that has a detachable keyboard.

System 1002 includes system board 1010, which represents a primary printed circuit board (PCB) to control the operation in system 1002. System board 1010 can be referred to as a motherboard or a mainboard in certain computer configurations. System board 1010 represents a rectangular system board, which is a traditional system board configuration, with a length and a width (x and y axis, not specifically labeled for orientation in system 1002) that are both at least twice a width or length dimension of the primary processor or host processor. Battery 1030 represents a battery for system 1002.

In one example, system board 1010 has gap 1012. Gap 1012 represents a cutout from system board 1010. The cutout can provide space for a double USM connector to be mounted to system board 1010. It will be understood that the location of gap 1012 in system board 1010 is implementation specific, and can occur anywhere in the system board.

FIG. 10B is a block diagram of an example of system 1002 with a double USM connector assembly. System 1004 is an example of system 1002 with additional components illustrated. It will be understood that the location of components in system 1004 is not necessarily exemplary of a practical system.

System board 1010 includes processor 1022, which represents a host processor or main processing unit for system 1002. Processor 1022 can be a central processing unit (CPU) or system on a chip (SOC) that includes a CPU or other processor. In one example, processor 1022 can include a graphics processing unit (GPU), which can be the same as the primary processor, or separate from the primary processor.

System board 1010 includes memory 1024, which represents operational memory for the computing device. The operational memory can be referred to as system memory. The operational memory generally is, or includes, volatile memory, which has indeterminate state if power is interrupted to the memory. Processor 1022 utilizes memory 1024 to control operation of system 1002. System 1004 includes battery 1030 to power the system.

System 1004 includes a double USM assembly. Module 1040 represents the modules of the double USM assembly. Connector (CONN) 1042 represents the USM connectors that connect the modules to system board 1010. Module 1040 represents add-in cards or boards. The module can be of any type describe. In one example, module 1040 represents at least two SSDs. Module 1040 includes stacked modules. In one example, the stacked module includes two modules with a thermal layer between them. The module assembly includes two USM connectors, one for each module.

Saving space in system 1004 with the double USM assembly can enable an increased size of battery 1030 relative to a system that would require two different module connectors. Alternatively, instead of increasing battery size, system 1004 can use the additional space for larger speakers, more antennas, or other components.

FIG. 10C is a block diagram of an example of a computer system with a double USM connector assembly mounted to a ruler board. System 1006 represents a computing system or a computing device. For example, system 1006 can be a laptop computer, a tablet computer, or a two-in-one device. The display for the device is not explicitly shown in system 1006, but can be a screen that covers device, or can be a display that connects via hinge, built on top of the chassis of system 1006, or connect with some other connector.

In one example, system 1006 has a clamshell design, where the processing elements and keyboard are fixed to the display element. In one example, system 1006 is a detachable computer, where the processor and display are part of a common unit that has a detachable keyboard. System 1006 can be an alternate example to system 1004 of FIG. 10B, with similar internal components but with a different system board design.

System 1006 includes system board 1050, which represents a primary printed circuit board (PCB) to control the operation in system 1006. System board 1050 can be referred to as a motherboard in certain computer configurations. System board 1050 represents a ruler board, with a length substantially longer than its width (or a width substantially longer than its length, depending on how the x axis and y axis are oriented in system 1006). Typically, a ruler board will have a first dimension that is less than double a width or length dimension of the primary processor or host processor, and a second dimension that is at least many multiples (e.g., at least 3 or 4) of the first dimension.

System board 1050 includes processor 1052, which represents a host processor or main processing unit for system 1006. Processor 1052 can be a central processing unit (CPU) or system on a chip (SOC) that includes a CPU or other processor. In one example, processor 1052 can include a graphics processing unit (GPU), which can be the same as the primary processor, or separate from the primary processor. System board 1050 includes memory 1054, which represents operational memory for the computing device. Processor 1052 utilizes memory 1054 to control operation of system 1006.

System 1006 includes a battery to power the system. System 1006 is illustrated with multiple separate battery components that straddle system board 1050. Battery 1032 can represent one portion or segment of the battery and battery 1034 can represent another portion or segment of the battery. While illustrated as substantially the same shape and size, there is no requirement for the different battery segments to be symmetrical or symmetrically configured within the chassis of system 1006. In one example, system 1006 can have more than two battery segments.

System 1006 includes one or more add-in cards connected to system board 1050, at least one of which can be a double USM assembly. System 1006 illustrates three add-in boards: add-in 1060, add-in 1070, and add-in 1080. System 1006 may include a single add-in board or can include multiple add-in boards. Module 1040 includes stacked modules. In one example, the stacked module includes two modules with a thermal layer between them. The module assembly includes two USM connectors, one for each module. In one example, add-in 1060 is connected to system board 1050 with connector (CONN) 1062. Add-in 1070 connects to system board 1050 through connector (CONN) 1072. Add-in 1080 connects to system board 1050 through connector (CONN) 1082.

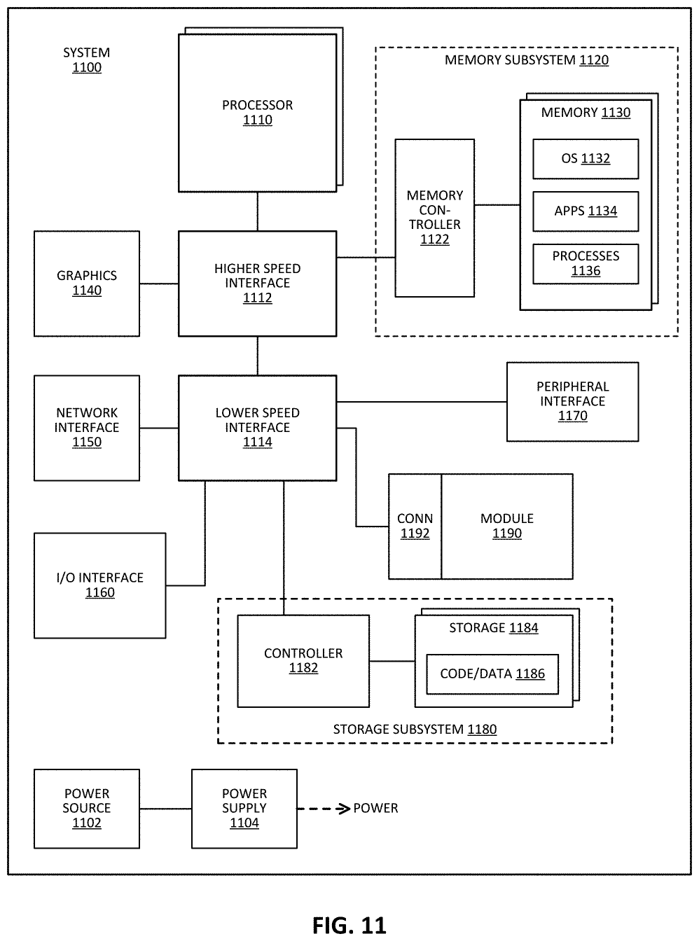

FIG. 11 is a block diagram of an example of a computing system in which a double USM connector assembly can be implemented. System 1100 represents a computing device in accordance with any example herein, and can be a laptop computer, a desktop computer, a tablet computer, a server, a gaming or entertainment control system, embedded computing device, or other electronic device.

System 1100 provides an example of a system that can implement a double USM connector with stacked modules in accordance with any example described. Module 1190 of system 1100 represents the stacked module, connected to the system board by connector (CONN) 1192. Module 1190 includes stacked modules. In one example, the stacked module includes two modules with a thermal layer between them. The module assembly includes two USM connectors, one for each module. In one example, module 1190 is a wireless communication card, and could thus be an example of a network interface 1150 or I/O interface 1160. In one example, module 1190 is an SSD, and could thus be an example of storage subsystem 1180.

System 1100 includes processor 1110 can include any type of microprocessor, central processing unit (CPU), graphics processing unit (GPU), processing core, or other processing hardware, or a combination, to provide processing or execution of instructions for system 1100. Processor 1110 can be a host processor device. Processor 1110 controls the overall operation of system 1100, and can be or include, one or more programmable general-purpose or special-purpose microprocessors, digital signal processors (DSPs), programmable controllers, application specific integrated circuits (ASICs), programmable logic devices (PLDs), or a combination of such devices.

In one example, system 1100 includes interface 1112 coupled to processor 1110, which can represent a higher speed interface or a high throughput interface for system components that need higher bandwidth connections, such as memory subsystem 1120 or graphics interface components 1140. Interface 1112 represents an interface circuit, which can be a standalone component or integrated onto a processor die. Interface 1112 can be integrated as a circuit onto the processor die or integrated as a component on a system on a chip. Where present, graphics interface 1140 interfaces to graphics components for providing a visual display to a user of system 1100. Graphics interface 1140 can be a standalone component or integrated onto the processor die or system on a chip. In one example, graphics interface 1140 can drive a high definition (HD) display or ultra high definition (UHD) display that provides an output to a user. In one example, the display can include a touchscreen display. In one example, graphics interface 1140 generates a display based on data stored in memory 1130 or based on operations executed by processor 1110 or both.

Memory subsystem 1120 represents the main memory of system 1100, and provides storage for code to be executed by processor 1110, or data values to be used in executing a routine. Memory subsystem 1120 can include one or more memory devices 1130 such as read-only memory (ROM), flash memory, one or more varieties of random-access memory (RAM) such as DRAM, 3DXP (three-dimensional crosspoint), or other memory devices, or a combination of such devices. Memory 1130 stores and hosts, among other things, operating system (OS) 1132 to provide a software platform for execution of instructions in system 1100. Additionally, applications 1134 can execute on the software platform of OS 1132 from memory 1130. Applications 1134 represent programs that have their own operational logic to perform execution of one or more functions. Processes 1136 represent agents or routines that provide auxiliary functions to OS 1132 or one or more applications 1134 or a combination. OS 1132, applications 1134, and processes 1136 provide software logic to provide functions for system 1100. In one example, memory subsystem 1120 includes memory controller 1122, which is a memory controller to generate and issue commands to memory 1130. It will be understood that memory controller 1122 could be a physical part of processor 1110 or a physical part of interface 1112. For example, memory controller 1122 can be an integrated memory controller, integrated onto a circuit with processor 1110, such as integrated onto the processor die or a system on a chip.

While not specifically illustrated, it will be understood that system 1100 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 1100 includes interface 1114, which can be coupled to interface 1112. Interface 1114 can be a lower speed interface than interface 1112. In one example, interface 1114 represents an interface circuit, which can include standalone components and integrated circuitry. In one example, multiple user interface components or peripheral components, or both, couple to interface 1114. Network interface 1150 provides system 1100 the ability to communicate with remote devices (e.g., servers or other computing devices) over one or more networks. Network interface 1150 can include an Ethernet adapter, wireless interconnection components, cellular network interconnection components, USB (universal serial bus), or other wired or wireless standards-based or proprietary interfaces. Network interface 1150 can exchange data with a remote device, which can include sending data stored in memory or receiving data to be stored in memory.

In one example, system 1100 includes one or more input/output (I/O) interface(s) 1160. I/O interface 1160 can include one or more interface components through which a user interacts with system 1100 (e.g., audio, alphanumeric, tactile/touch, or other interfacing). Peripheral interface 1170 can include any hardware interface not specifically mentioned above. Peripherals refer generally to devices that connect dependently to system 1100. A dependent connection is one where system 1100 provides the software platform or hardware platform or both on which operation executes, and with which a user interacts.

In one example, system 1100 includes storage subsystem 1180 to store data in a nonvolatile manner. In one example, in certain system implementations, at least certain components of storage 1180 can overlap with components of memory subsystem 1120. Storage subsystem 1180 includes storage device(s) 1184, which can be or include any conventional medium for storing large amounts of data in a nonvolatile manner, such as one or more magnetic, solid state, 3DXP, or optical based disks, or a combination. Storage 1184 holds code or instructions and data 1186 in a persistent state (i.e., the value is retained despite interruption of power to system 1100). Storage 1184 can be generically considered to be a “memory,” although memory 1130 is typically the executing or operating memory to provide instructions to processor 1110. Whereas storage 1184 is nonvolatile, memory 1130 can include volatile memory (i.e., the value or state of the data is indeterminate if power is interrupted to system 1100). In one example, storage subsystem 1180 includes controller 1182 to interface with storage 1184. In one example controller 1182 is a physical part of interface 1114 or processor 1110, or can include circuits or logic in both processor 1110 and interface 1114.

Power source 1102 provides power to the components of system 1100. More specifically, power source 1102 typically interfaces to one or multiple power supplies 1104 in system 1100 to provide power to the components of system 1100. In one example, power supply 1104 includes an AC to DC (alternating current to direct current) adapter to plug into a wall outlet. Such AC power can be renewable energy (e.g., solar power) power source 1102. In one example, power source 1102 includes a DC power source, such as an external AC to DC converter. In one example, power source 1102 or power supply 1104 includes wireless charging hardware to charge via proximity to a charging field. In one example, power source 1102 can include an internal battery or fuel cell source.

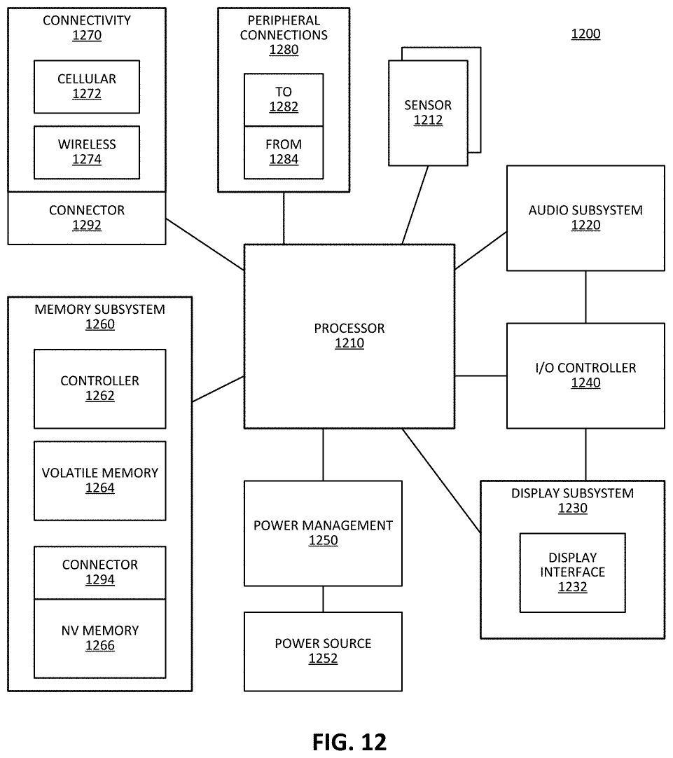

FIG. 12 is a block diagram of an example of a mobile device in which a double USM connector assembly can be implemented. System 1200 represents a mobile computing device, such as a computing tablet, a mobile phone or smartphone, wearable computing device, or other mobile device, or an embedded computing device. It will be understood that certain of the components are shown generally, and not all components of such a device are shown in system 1200.

In one example, connectivity 1270 represents wireless connectivity for system 1200, and is connected to a processor SOC for processor 1210 via connector 1292. Connector 1292 represents stacked modules. In one example, one or more peripherals of peripheral connections 1280 are connected with double USM connector assembly, although the connector is not explicitly shown in system 1200. In one example, memory subsystem 1260 includes nonvolatile (NV) memory 1266, which can be a nonvolatile storage board connected to processor 1210 with a double USM assembly, represented with connector 1294. Any stacked module assembly implemented includes multiple modules. In one example, the stacked module includes two modules with a thermal layer between them. The module assembly includes two USM connectors, one for each module.

System 1200 includes processor 1210, which performs the primary processing operations of system 1200. Processor 1210 can be a host processor device. Processor 1210 can include one or more physical devices, such as microprocessors, application processors, microcontrollers, programmable logic devices, or other processing means. The processing operations performed by processor 1210 include the execution of an operating platform or operating system on which applications and device functions are executed. The processing operations include operations related to I/O (input/output) with a human user or with other devices, operations related to power management, operations related to connecting system 1200 to another device, or a combination. The processing operations can also include operations related to audio I/O, display I/O, or other interfacing, or a combination. Processor 1210 can execute data stored in memory. Processor 1210 can write or edit data stored in memory.

In one example, system 1200 includes one or more sensors 1212. Sensors 1212 represent embedded sensors or interfaces to external sensors, or a combination. Sensors 1212 enable system 1200 to monitor or detect one or more conditions of an environment or a device in which system 1200 is implemented. Sensors 1212 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 1212 can also include sensors for biometric systems such as fingerprint recognition systems, face detection or recognition systems, or other systems that detect or recognize user features. Sensors 1212 should be understood broadly, and not limiting on the many different types of sensors that could be implemented with system 1200. In one example, one or more sensors 1212 couples to processor 1210 via a frontend circuit integrated with processor 1210. In one example, one or more sensors 1212 couples to processor 1210 via another component of system 1200.

In one example, system 1200 includes audio subsystem 1220, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into system 1200, or connected to system 1200. In one example, a user interacts with system 1200 by providing audio commands that are received and processed by processor 1210.

Display subsystem 1230 represents hardware (e.g., display devices) and software components (e.g., drivers) that provide a visual display for presentation to a user. In one example, the display includes tactile components or touchscreen elements for a user to interact with the computing device. Display subsystem 1230 includes display interface 1232, which includes the particular screen or hardware device used to provide a display to a user. In one example, display interface 1232 includes logic separate from processor 1210 (such as a graphics processor) to perform at least some processing related to the display. In one example, display subsystem 1230 includes a touchscreen device that provides both output and input to a user. In one example, display subsystem 1230 includes a high definition (HD) or ultra-high definition (UHD) display that provides an output to a user. In one example, display subsystem includes or drives a touchscreen display. In one example, display subsystem 1230 generates display information based on data stored in memory or based on operations executed by processor 1210 or both.

I/O controller 1240 represents hardware devices and software components related to interaction with a user. I/O controller 1240 can operate to manage hardware that is part of audio subsystem 1220, or display subsystem 1230, or both. Additionally, I/O controller 1240 illustrates a connection point for additional devices that connect to system 1200 through which a user might interact with the system. For example, devices that can be attached to system 1200 might include microphone devices, speaker or stereo systems, video systems or other display device, keyboard or keypad devices, buttons/switches, or other I/O devices for use with specific applications such as card readers or other devices.

As mentioned above, I/O controller 1240 can interact with audio subsystem 1220 or display subsystem 1230 or both. For example, input through a microphone or other audio device can provide input or commands for one or more applications or functions of system 1200. Additionally, audio output can be provided instead of or in addition to display output. In another example, if display subsystem includes a touchscreen, the display device also acts as an input device, which can be at least partially managed by I/O controller 1240. There can also be additional buttons or switches on system 1200 to provide I/O functions managed by I/O controller 1240.

In one example, I/O controller 1240 manages devices such as accelerometers, cameras, light sensors or other environmental sensors, gyroscopes, global positioning system (GPS), or other hardware that can be included in system 1200, or sensors 1212. The input can be part of direct user interaction, as well as providing environmental input to the system to influence its operations (such as filtering for noise, adjusting displays for brightness detection, applying a flash for a camera, or other features).

In one example, system 1200 includes power management 1250 that manages battery power usage, charging of the battery, and features related to power saving operation. Power management 1250 manages power from power source 1252, which provides power to the components of system 1200. In one example, power source 1252 includes an AC to DC (alternating current to direct current) adapter to plug into a wall outlet. Such AC power can be renewable energy (e.g., solar power, motion based power). In one example, power source 1252 includes only DC power, which can be provided by a DC power source, such as an external AC to DC converter. In one example, power source 1252 includes wireless charging hardware to charge via proximity to a charging field. In one example, power source 1252 can include an internal battery or fuel cell source.

Memory subsystem 1260 includes memory device(s) for storing information in system 1200. Memory subsystem 1260 can include nonvolatile (NV) memory 1266 (state does not change if power to the memory device is interrupted) or volatile memory 1264 (state is indeterminate if power to the memory device is interrupted), or a combination of volatile and nonvolatile memory. Memory subsystem 1260 can store application data, user data, music, photos, documents, or other data, as well as system data (whether long-term or temporary) related to the execution of the applications and functions of system 1200. In one example, memory subsystem 1260 includes controller 1262 (which could also be considered part of the control of system 1200, and could potentially be considered part of processor 1210). Controller 1262 includes a scheduler to generate and issue commands to control access to a controlled memory device, volatile memory 1264 or NV memory 1266. In one example, controller represents more than one controller. In one example, memory subsystem 1260 includes different controllers for volatile memory and nonvolatile memory.

Connectivity 1270 includes hardware devices (e.g., wireless or wired connectors and communication hardware, or a combination of wired and wireless hardware) and software components (e.g., drivers, protocol stacks) to enable system 1200 to communicate with external devices. The external device could be separate devices, such as other computing devices, wireless access points or base stations, as well as peripherals such as headsets, printers, or other devices. In one example, system 1200 exchanges data with an external device for storage in memory or for display on a display device. The exchanged data can include data to be stored in memory, or data already stored in memory, to read, write, or edit data.

Connectivity 1270 can include multiple different types of connectivity. To generalize, system 1200 is illustrated with cellular connectivity 1272 and wireless connectivity 1274. Cellular connectivity 1272 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), 5G, or other cellular service standards. Wireless connectivity 1274 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 1280 include hardware interfaces and connectors, as well as software components (e.g., drivers, protocol stacks) to make peripheral connections. It will be understood that system 1200 could both be a peripheral device (“to” 1282) to other computing devices, as well as have peripheral devices (“from” 1284) connected to it. System 1200 commonly has a “docking” connector to connect to other computing devices for purposes such as managing (e.g., downloading, uploading, changing, synchronizing) content on system 1200. Additionally, a docking connector can allow system 1200 to connect to certain peripherals that allow system 1200 to control content output, for example, to audiovisual or other systems.

In addition to a proprietary docking connector or other proprietary connection hardware, system 1200 can make peripheral connections 1280 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), or other type.

In general with respect to the descriptions herein, in one aspect a connector assembly includes: a top-mount ultra-slim module (USMt) connector having an offset lead frame to bridge from pads on a first surface of a first module board to a first surface of a system board when the first surface of the first module board is vertically offset from the first surface of the system board; an inline ultra-slim module (USMi) connector having an inline lead frame to bridge from pads on a first surface of a second module board to a second surface of the system board, wherein the first surface of the second module board is vertically inline with the second surface of the system board, the USMi connector to be mounted on the second surface of the system board opposite the USMt connector on the first surface of the system board; first threaded mounting studs to attach the USMt connector to the first surface of the system board; and second threaded mounting studs to attach the USMi connector to the second surface of the system board, opposite to the USMt connector.

In accordance with an example of the connector assembly, the first surface of the system board comprises a top side of a computer motherboard and the second surface of the system board comprises a bottom side of the computer motherboard. In accordance with any preceding example of the connector assembly, in one example, the first module board and the second module board are different types of modules. In accordance with any preceding example of the connector assembly, in one example, the first module board and the second module board are a same type of module. In accordance with any preceding example of the connector assembly, in one example, the connector assembly includes a thermal layer, with the first module board mounted to a first surface of the thermal layer and the second module board mounted to a second surface of the thermal layer. In accordance with any preceding example of the connector assembly, in one example, the thermal layer comprises a metallic plate. In accordance with any preceding example of the connector assembly, in one example, the metallic plate comprises an aluminum-copper alloy plate. In accordance with any preceding example of the connector assembly, in one example, the first module board is mounted to posts on the thermal layer with a sliding plate. In accordance with any preceding example of the connector assembly, in one example, the second module board is mounted to the thermal layer with a nut and bolt fastener. In accordance with any preceding example of the connector assembly, in one example, the USMt connector includes: a first alignment frame to hold the offset lead frame, including posts to mate with first alignment holes of the system board and with second alignment holes of the first module board; and a first electrically conductive cover to secure over the first alignment frame, the first cover including openings to receive screws to secure the first cover to first screw holes in the system board and second screw holes in the first module board, the first cover to electrically couple via the screws to ground planes of the system board and the first module board; and wherein the USMi connector includes: a second alignment frame to hold the inline lead frame, including posts to mate with third alignment holes of the system board and with fourth alignment holes of the second module board; and a second electrically conductive cover to secure over the second alignment frame, the second cover including openings to receive screws to secure the second cover to third screw holes in the system board and fourth screw holes in the second module board, the second cover to electrically couple via the screws to ground planes of the system board and the second module board.

In general with respect to the descriptions herein, in one aspect, a computer system includes: a system board having a cutout to accommodate a stacked module, the system board including a first system board surface and a second system board surface; and a stacked module device including a top-mount ultra-slim module (USMt) connector having an offset lead frame to bridge from pads on a first surface of a first module board to the first system board surface when the first surface of the first module board is vertically offset from the first system board surface; and an inline ultra-slim module (USMi) connector having an inline lead frame to bridge from pads on a first surface of a second module board to the second system board surface, wherein the first surface of the second module board is vertically inline with the second system board surface, the USMi connector mounted on the second system board surface opposite the USMt connector on the first system board surface.

In accordance with an example of the computer system, the first module board and the second module board are different types of modules. In accordance with any preceding example of the computer system, in one example, the first module board and the second module board are a same type of module. In accordance with any preceding example of the computer system, in one example, the computer system includes a thermal layer, with the first module board mounted to a first surface of the thermal layer and the second module board mounted to a second surface of the thermal layer. In accordance with any preceding example of the computer system, in one example, the thermal layer comprises a metallic plate. In accordance with any preceding example of the computer system, in one example, the metallic plate comprises an aluminum-copper alloy plate. In accordance with any preceding example of the computer system, in one example, the first module board is mounted to posts on the thermal layer with a sliding plate. In accordance with any preceding example of the computer system, in one example, the second module board is mounted to the thermal layer with a nut and bolt fastener. In accordance with any preceding example of the computer system, in one example, the USMt connector includes: a first alignment frame to hold the offset lead frame, including posts to mate with first alignment holes of the system board and with second alignment holes of the first module board; and a first electrically conductive cover to secure over the first alignment frame, the first cover including openings to receive screws to secure the first cover to first screw holes in the system board and second screw holes in the first module board, the first cover to electrically couple via the screws to ground planes of the system board and the first module board; and wherein the USMi connector includes: a second alignment frame to hold the inline lead frame, including posts to mate with third alignment holes of the system board and with fourth alignment holes of the second module board; and a second electrically conductive cover to secure over the second alignment frame, the second cover including openings to receive screws to secure the second cover to third screw holes in the system board and fourth screw holes in the second module board, the second cover to electrically couple via the screws to ground planes of the system board and the second module board. In accordance with any preceding example of the computer system, in one example, the computer system includes one or more of: a host processor device mounted on the system board; a display communicatively coupled to a host processor of the system board; a network interface communicatively coupled to a host processor of the system board; or a battery to power the computer system.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A connector assembly, comprising:
a top-mount ultra-slim module (USMt) connector having an offset lead frame to bridge from pads on a first surface of a first module board to a first surface of a system board when the first surface of the first module board is vertically offset from the first surface of the system board;
an inline ultra-slim module (USMi) connector having an inline lead frame to bridge from pads on a first surface of a second module board to a second surface of the system board, wherein the first surface of the second module board is vertically inline with the second surface of the system board, the USMi connector to be mounted on the second surface of the system board opposite the USMt connector on the first surface of the system board;
first threaded mounting studs to attach the USMt connector to the first surface of the system board; and
second threaded mounting studs to attach the USMi connector to the second surface of the system board, opposite to the USMt connector.

2. The connector assembly of claim 1, wherein the first surface of the system board comprises a top side of a computer motherboard and the second surface of the system board comprises a bottom side of the computer motherboard.

3. The connector assembly of claim 1, wherein the first module board and the second module board are different types of modules.

4. The connector assembly of claim 1, wherein the first module board and the second module board are a same type of module.

5. The connector assembly of claim 1, further comprising a thermal layer, with the first module board mounted to a first surface of the thermal layer and the second module board mounted to a second surface of the thermal layer.

6. The connector assembly of claim 5, wherein the thermal layer comprises a metallic plate.

7. The connector assembly of claim 6, wherein the metallic plate comprises an aluminum-copper alloy plate.

8. The connector assembly of claim 5, wherein the first module board is mounted to posts on the thermal layer with a sliding plate.

9. The connector assembly of claim 5, wherein the second module board is mounted to the thermal layer with a nut and bolt fastener.

10. The connector assembly of claim 1,
wherein the USMt connector includes:
a first alignment frame to hold the offset lead frame, including posts to mate with first alignment holes of the system board and with second alignment holes of the first module board; and
a first electrically conductive cover to secure over the first alignment frame, the first cover including openings to receive screws to secure the first cover to first screw holes in the system board and second screw holes in the first module board, the first cover to electrically couple via the screws to ground planes of the system board and the first module board; and
wherein the USMi connector includes:
a second alignment frame to hold the inline lead frame, including posts to mate with third alignment holes of the system board and with fourth alignment holes of the second module board; and
a second electrically conductive cover to secure over the second alignment frame, the second cover including openings to receive screws to secure the second cover to third screw holes in the system board and fourth screw holes in the second module board, the second cover to electrically couple via the screws to ground planes of the system board and the second module board.

11. A computer system comprising:
a system board having a cutout to accommodate a stacked module, the system board including a first system board surface and a second system board surface; and
a stacked module device including
a top-mount ultra-slim module (USMt) connector having an offset lead frame to bridge from pads on a first surface of a first module board to the first system board surface when the first surface of the first module board is vertically offset from the first system board surface; and
an inline ultra-slim module (USMi) connector having an inline lead frame to bridge from pads on a first surface of a second module board to the second system board surface, wherein the first surface of the second module board is vertically inline with the second system board surface, the USMi connector mounted on the second system board surface opposite the USMt connector on the first system board surface.

12. The computer system of claim 11, wherein the first module board and the second module board are different types of modules.

13. The computer system of claim 11, wherein the first module board and the second module board are a same type of module.

14. The computer system of claim 11, further comprising a thermal layer, with the first module board mounted to a first surface of the thermal layer and the second module board mounted to a second surface of the thermal layer.

15. The computer system of claim 14, wherein the thermal layer comprises a metallic plate.

16. The computer system of claim 15, wherein the metallic plate comprises an aluminum-copper alloy plate.

17. The computer system of claim 14, wherein the first module board is mounted to posts on the thermal layer with a sliding plate.

18. The computer system of claim 14, wherein the second module board is mounted to the thermal layer with a nut and bolt fastener.

19. The computer system of claim 11,
wherein the USMt connector includes:
a first alignment frame to hold the offset lead frame, including posts to mate with first alignment holes of the system board and with second alignment holes of the first module board; and
a first electrically conductive cover to secure over the first alignment frame, the first cover including openings to receive screws to secure the first cover to first screw holes in the system board and second screw holes in the first module board, the first cover to electrically couple via the screws to ground planes of the system board and the first module board; and
wherein the USMi connector includes:
a second alignment frame to hold the inline lead frame, including posts to mate with third alignment holes of the system board and with fourth alignment holes of the second module board; and
a second electrically conductive cover to secure over the second alignment frame, the second cover including openings to receive screws to secure the second cover to third screw holes in the system board and fourth screw holes in the second module board, the second cover to electrically couple via the screws to ground planes of the system board and the second module board.

20. The computer system of claim 11, further comprising one or more of:
a host processor device mounted on the system board;
a display communicatively coupled to a host processor of the system board;
a network interface communicatively coupled to a host processor of the system board; or
a battery to power the computer system.
